(19) United States
(12) Patent Application Publication
(10) Pub. No.: US 2025/0287785 A1
(43) Pub. Date: Sep. 11, 2025

(54) DISPLAY DEVICE AND METHOD OF MANUFACTURING THE SAME

(71) Applicant: Samsung Display Co., LTD., Yongin-si (KR)

(72) Inventors: Jae Been LEE, Yongin-si (KR); Sin Chul KANG, Yongin-si (KR); Na Rae PARK, Yongin-si (KR); Dae Ho SONG, Yongin-si (KR); Ju Won YOON, Yongin-si (KR); Lok Gam JUNG, Yongin-si (KR); Mi Yeon CHO, Yongin-si (KR); Ye Hwan CHOI, Yongin-si (KR)

(21) Appl. No.: 18/986,364

(22) Filed: Dec. 18, 2024

(30) Foreign Application Priority Data
Mar. 8, 2024 (KR) 10-2024-0033311

(51) Int. Cl. H10K 59/122; H10K 59/12

(52) U.S. Cl. CPC H10K 59/122; H10K 59/1201

(57) ABSTRACT

A display device includes a substrate, a pixel circuit layer above the substrate, anodes spaced apart from each other above the pixel circuit layer, a pixel-defining layer partially on the pixel circuit layer and the anodes, and at least one trench between the anodes, partially penetrating the pixel-defining layer and the pixel circuit layer, and having a width of about 70 nm or less.

### CROSS-REFERENCE TO RELATED APPLICATION

The present application claims priority to, and the benefit of, Korean Patent Application No. 10-2024-0033311, filed on Mar. 8, 2024, in the Korean Intellectual Property Office, the entire disclosure of which is incorporated herein by reference.

### BACKGROUND

### 1. Field

Aspects of embodiments of the present disclosure relate to a display device, and a method of manufacturing the display device.

### 2. Description of the Related Art

As information technology develops, the importance of a display device, which is a connection medium between a user and information, has been highlighted. In response to this, a use of a display device such as a liquid crystal display device and an organic light-emitting display device is increasing.

### SUMMARY

Embodiments of the present disclosure provide a display device in which lateral leakage is reduced (or removed), and a method of manufacturing the display device.

According to embodiments of the present disclosure, a display device includes a substrate, a pixel circuit layer above the substrate, anodes spaced apart from each other above the pixel circuit layer, a pixel-defining layer partially on the pixel circuit layer and the anodes, and at least one trench between the anodes, partially penetrating the pixel-defining layer and the pixel circuit layer, and having a width of about 70 nm or less.

The display device may further include a spacer above a portion of the pixel-defining layer adjacent to the trench.

A width of the spacer may be substantially equal to the width of the trench.

The spacer may have a symmetrical structure with respect to the trench.

Shapes of first portions of the spacer facing the trench, and shapes of second portions of the spacer not facing the trench, may be different from each other.

The first portions may be round, and the second portions may be flat.

The first portions may be flat, and the second portions may be round.

According to one or more other embodiments of the present disclosure, a method of manufacturing a display device includes patterning anodes above a pixel circuit layer above a substrate, forming a pixel-defining layer above the pixel circuit layer and the anodes, patterning a hard mask above the pixel-defining layer, patterning a spacer above the pixel-defining layer, and forming at least one trench between the anodes, and partially penetrating the pixel-defining layer and the pixel circuit layer.

The patterning of the hard mask may include forming the hard mask above the pixel-defining layer, forming a photoresist above the hard mask, exposing and developing the photoresist using a light source, etching the hard mask, and removing the photoresist.

The light source may include a KrF exposer, ArF exposer, or ArFi exposer.

The patterning of the spacer may include forming a spacer material above the hard mask and the pixel-defining layer, and removing portions of the spacer material that overlap the hard mask and the trench.

A thickness of the spacer may be at least about 2000 Å.

A width of the spacer may be substantially equal to the width of the trench.

The spacer may have a symmetrical structure with respect to the trench.

Shapes of first portions of the spacer facing the trench, and shapes of second portions of the spacer not facing the trench, may be different from each other.

The first portions may be round, and the second portions are flat.

The first portions may be flat, and the second portions may be round.

A width of the trench may be about 70 nm or less.

The method may further include removing the hard mask.

The method may further include removing the spacer.

According to the embodiments of the present disclosure, lateral leakage may be reduced (or removed), thereby improving the efficiency, reliability, and lifespan characteristics of a display device.

However, aspects of the disclosure are not limited to the above-described aspects, and may be variously expanded within a range that does not deviate from the spirit and scope of the disclosure.

### BRIEF DESCRIPTION OF THE DRAWINGS

The above and other aspects of the present disclosure will become more apparent by describing, in further detail, embodiments thereof with reference to the accompanying drawings, in which:

FIG. 1 is a block diagram of a display device in accordance with one or more embodiments.

FIG. 2 is a block diagram of a sub-pixel in accordance with one or more embodiments.

FIG. 3 is a plan view of a display panel in accordance with one or more embodiments.

FIG. 4 is a cross-sectional view of a display panel in accordance with one or more embodiments.

FIG. 5 is a cross-sectional view of a display panel in accordance with one or

more embodiments.

FIG. 6 is a plan view of a pixel in accordance with one or more embodiments.

FIG. 7 a cross-sectional view taken along the line I-I′ of FIG. 6 in accordance with one or more embodiments.

FIG. 8 is a cross-sectional view of a light-emitting structure in accordance with one or more embodiments.

FIG. 9 is a cross-sectional view of a light-emitting structure in accordance with one or more embodiments.

FIG. 10 is a cross-sectional view taken along the line I-I′ of FIG. 6 in accordance with one or more embodiments.

FIG. 11 is a cross-sectional view taken along the line I-I′ of FIG. 6 in accordance with one or more embodiments.

FIG. 12 is a flowchart describing a method of manufacturing a display device in accordance with one or more embodiments.

FIGS. 13 to 18 are cross-sectional views illustrating steps of a method of manufacturing the display device in accordance with one or more embodiments.

FIG. 19 is a block diagram of a display system in accordance with one or more embodiments.

FIGS. 20 to 23 are perspective views of application examples of the display system of FIG. 19 in accordance with one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that the present disclosure covers all modifications, equivalents, and replacements within the idea and technical scope of the present disclosure, that each of the features of embodiments of the present disclosure may be combined with each other, in part or in whole, and technically various interlocking and operating are possible, and that each embodiment may be implemented independently of each other, or may be implemented together in an association, unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the DR1-axis, the DR2-axis, and/or the DR3-axis are not limited to three axes of a rectangular coordinate system, and may be interpreted in a broader sense. For example, the DR1-axis, the DR2-axis, and the DR3-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

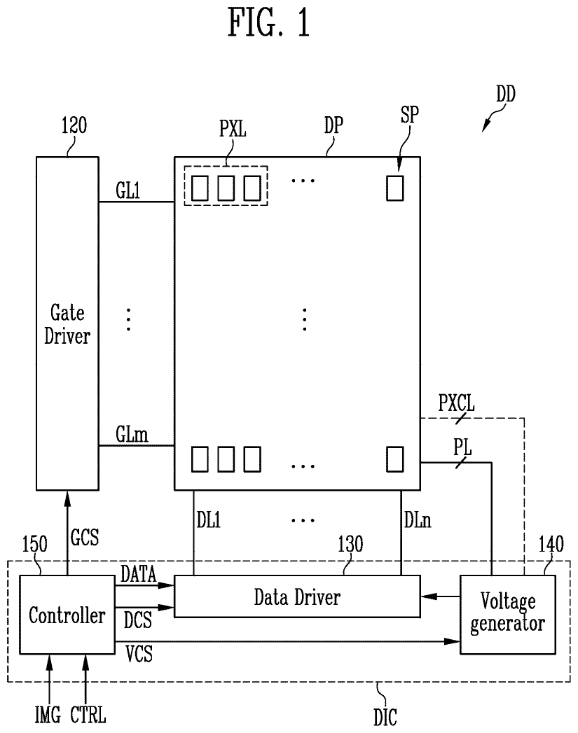

FIG. 1 is a block diagram of a display device in accordance with one or more embodiments.

Referring to FIG. 1, a display device DD may include a display panel DP, a gate driver 120, a data driver 130, a voltage generator 140, and a controller 150.

The display panel DP includes sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

The sub-pixels SP may generate light of two or more colors. For example, the sub-pixels SP may respectively generate light of a color, such as red, green, blue, cyan, magenta, yellow, or the like.

Two or more of the sub-pixels SP may configure one pixel PXL. For example, the pixel PXL may include three sub-pixels SP as shown in FIG. 1. As such, the pixel PXL may emit light of various colors and various luminance depending on a combination of light emitted from the sub-pixels SP included therein.

The gate driver 120 is connected to the sub-pixels SP arranged in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating the start of each frame, a horizontal synchronization signal, and the like.

The gate driver 120 may be located on one side of the display panel DP. However, embodiments are not limited thereto. For example, the gate driver 120 may be divided into two or more physically and/or logically separated drivers, and the drivers may be respectively located on one side of the display panel DP and the other side of the display panel DP opposite to the one side. As described above, the gate driver 120 may be located around the display panel DP in various forms according to the embodiments.

The data driver 130 is connected to the sub-pixels SP arranged in a column direction through the first to n-th data lines DL1 to DLn. The data driver 130 receives image data DATA and data control signal DCS from the controller 150. The data driver 130 operates in response to the data control signal DCS. In embodiments, the data control signal DCS may include a source start signal, a source shift clock, a source output enable signal, and the like.

The data driver 130 may receive voltages from the voltage generator 140. The data driver 130 may use the received voltages to apply data signals having grayscale voltages corresponding to the image data DATA to the first to n-th data lines DL1 to DLn. When a gate signal is applied to each of the first to m-th gate lines GL1 to GLm, data signals corresponding to the image data DATA may be applied to the first to n-th data lines DL1 to DLn. Accordingly, the sub-pixels SP may generate light corresponding to the data signals, and the display panel DP may display an image.

In some embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 is configured to generate a plurality of voltages and provide the generated voltages to components of the display device DD, such as the gate driver 120, the data driver 130, and the controller 150. The voltage generator 140 may generate a plurality of voltages by receiving an input voltage from the outside of the display device DD and regulating the received voltage.

The voltage generator 140 may generate a first power voltage and a second power voltage. The generated first and second power voltages may be provided to the sub-pixels SP through the power lines PL. In other embodiments, at least one of the first and second power voltages may be provided from the outside of the display device DD.

In addition, the voltage generator 140 may provide various voltages and/or signals. For example, the voltage generator 140 may provide one or more initialization voltages applied to the sub-pixels SP. For example, during a sensing operation to sense electrical characteristics of transistors and/or light-emitting elements of the sub-pixels SP, a predetermined reference voltage may be applied to the first to n-th data lines DL1 to DLn, and the voltage generator 140 may generate the reference voltage to transmit it to the data driver 130. For example, during a display operation for displaying an image on the display panel DP, common pixel control signals may be applied to the sub-pixels SP, and the voltage generator 140 may generate the pixel control signals. In embodiments, the voltage generator 140 may provide pixel control signals to the sub-pixels SP through a pixel control lines PXCL. FIG. 1 illustrates that the pixel control lines PXCL are connected between the voltage generator 140 and the display panel DP, but embodiments are not limited thereto. For example, the pixel control lines PXCL may be connected between the gate driver 120 and the display panel DP. In this case, the pixel control signals may be transmitted from the voltage generator 140 to the pixel control lines PXCL through the gate driver 120.

The controller 150 controls various operations of the display device DD. The controller 150 receives input image data IMG and a control signal CTRL corresponding thereto, from the outside. The controller 150 may provide the gate control signal GCS, the data control signal DCS, and the voltage control signal VCS in response to the control signal CTRL.

The controller 150 may convert the input image data IMG to be suitable for the display device DD or the display panel DP to output the image data DATA. In embodiments, the controller 150 may output the image data DATA by aligning the input image data IMG to be suitable for the sub-pixels SP of a row unit.

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally separate components within one driver integrated circuit DIC. In other embodiments, at least one of the data driver 130, the voltage generator 140, and the controller 150 may be provided as a component separated from the driver integrated circuit DIC.

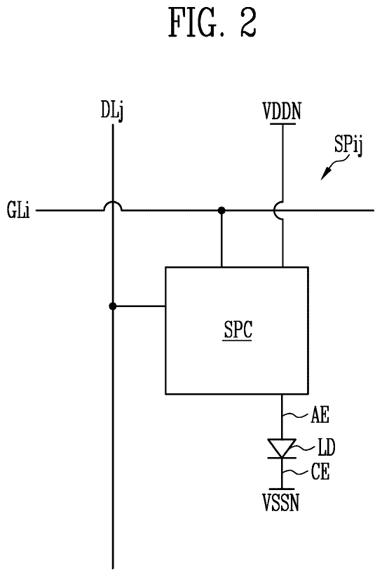

FIG. 2 is a block diagram of a sub-pixel in accordance with one or more embodiments. In FIG. 2, among the sub-pixels SP of FIG. 1, a sub-pixel SPij located in an i-th row (i is an integer greater than or equal to 1 and less than or equal to m) and a j-th column (j is an integer greater than or equal to 1 and less than or equal to n) is illustrated as an example.

Referring to FIG. 2, the sub-pixel SPij may include a sub-pixel circuit SPC and a light-emitting element LD.

The light-emitting element LD is connected between the first power voltage node VDDN and a second power voltage node VSSN. The first power voltage node VDDN is connected to one of the power lines PL in FIG. 1 to receives the first power voltage. The second power voltage node VSSN is connected to another one of the power lines PL in FIG. 1 to receives the second power voltage. The first power voltage may have a higher voltage level than the second power voltage.

The light-emitting element LD is connected between the anode AE and the cathode CE. The anode AE may be connected to the first power voltage node VDDN through the sub-pixel circuit SPC. For example, the anode AE may be connected to the first power voltage node VDDN through one or more transistors included in the sub-pixel circuit SPC. The cathode CE may be connected to the second power voltage node VSSN. The light-emitting element LD is configured to emit light according to a current flowing from the anode AE to the cathode CE.

The sub-pixel circuit SPC may be connected to an i-th gate line GLi of the first to m-th gate lines GL1 to GLm of FIG. 1 and a j-th data line DLj of the first to n-th data lines DL1 to DLn of FIG. 1. In response to the gate signal received through the i-th gate line GLi, the sub-pixel circuit SPC controls the light-emitting element LD to emit light according to the data signal received through the j-th data line DLj. In embodiments, the sub-pixel circuit SPC may be further connected to the pixel control lines PXCL of FIG. 1. In this case, the sub-pixel circuit SPC may control the light-emitting element LD in further response to pixel control signals received through the pixel control lines PXCL.

For these operations, the sub-pixel circuit SPC may include circuit elements, for example transistors and one or more capacitors.

The transistors of the sub-pixel circuit SPC may include P-type transistors and/or N-type transistors. In embodiments, the transistors of the sub-pixel circuit SPC may include a metal oxide semiconductor field effect transistor (MOSFET). In embodiments, the transistors of the sub-pixel circuit SPC may include an amorphous silicon semiconductor, a monocrystalline silicon semiconductor, a polycrystalline silicon semiconductor, and an oxide semiconductor.

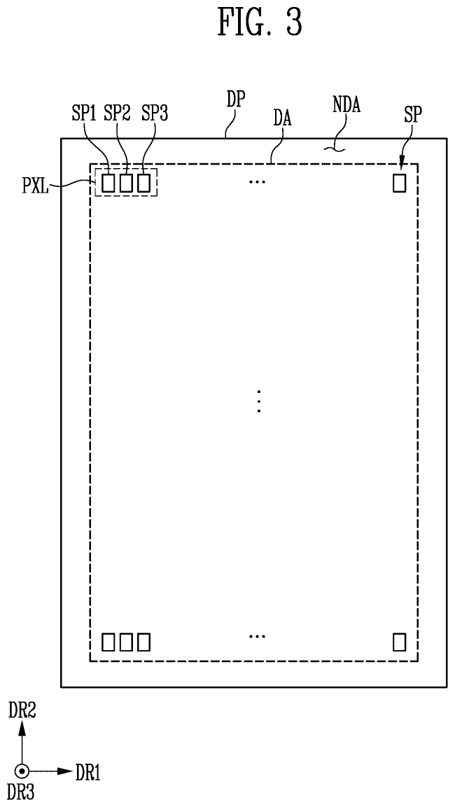

FIG. 3 is a plan view of a display panel in accordance with one or more embodiments.

Referring to FIG. 3, the display panel DP may include a display area DA and a non-display area NDA. The display panel DP displays an image through the display area DA. The non-display area NDA is located around the display area DA (e.g., in plan view).

The display panel DP includes sub-pixels SP in the display area DA. The sub-pixels SP may be arranged along a first direction DR1, and along a second direction DR2 that crosses the first direction DR1. For example, the sub-pixels SP may be arranged in a matrix form along the first direction DR1 and the second direction DR2. As another example, the sub-pixels SP may be arranged in a zigzag form along first direction DR1 and second direction DR2. The arrangement of the sub-pixels SP may vary in some embodiments. The first direction DR1 may be a row direction, and the second direction DR2 may be a column direction.

Two or more of the plurality of sub-pixels SP may configure one pixel PXL. FIG. 3 illustrates that the pixel PXL includes three sub-pixels SP1, SP2, and SP3, but embodiments are not limited thereto. For example, the pixel PXL may include two sub-pixels SP. Hereinafter, for better understanding and ease of description, it is assumed that the pixel PXL includes the first to third sub-pixels SP1, SP2, and SP3.

Each of the first to third sub-pixels SP1, SP2, and SP3 may generate light of one of various colors, such as red, green, blue, cyan, magenta, and/or yellow. Hereinafter, for clear and brief description, it is assumed that the first sub-pixel SP1 is configured to generate red-colored light, the second sub-pixel SP2 is configured to generate green-colored light, and the third sub-pixel SP3 is configured to generate blue-colored light.

Each of the first to third sub-pixels SP1, SP2, and SP3 may include at least one light-emitting element configured to generate light. In embodiments, the light-emitting elements of the first to third sub-pixels SP1, SP2, and SP3 may generate light of the same color. For example, the light-emitting elements of the first to third sub-pixels SP1, SP2, and SP3 may generate blue-colored light. In other embodiments, the light-emitting elements of the first to third sub-pixels SP1, SP2, and SP3 may generate light of different respective colors. For example, the light-emitting elements of the first to third sub-pixels SP1, SP2, and SP3 may generate light of red, green, and blue colors, respectively.

As the display panel DP, a self-luminous display panel, such as an LED display panel using a micro-scale or nano-scale light-emitting diode as a light-emitting element, and an organic light-emitting display panel using an organic light-emitting diode as a light-emitting element, may be used.

A constituent element to control the sub-pixels SP may be located in the non-display area NDA. Wires connected to the sub-pixels SP, for example, the first to m-th gate lines GL1 to GLm, the first to n-th data lines DL1 to DLn, the power lines PL, and the pixel control lines PXCL shown in FIG. 1 may be located in the non-display area NDA.

At least one of the gate driver 120, the data driver 130, the voltage generator 140, and the controller 150 in FIG. 1 may be located in the non-display area NDA of the display panel DP. The gate driver 120 may be located in the non-display area NDA. In this case, the data driver 130, the voltage generator 140, and the controller 150 may be implemented as the driver integrated circuit DIC of FIG. 1 separated from the display panel DP, and the driver integrated circuit DIC may be connected to wires located in the non-display area NDA. In other embodiments, the gate driver 120 may be implemented as one integrated circuit separated from the display panel DP together with the data driver 130, the voltage generator 140, and the controller 150.

In embodiments, the display area DA may have various shapes. The display area DA may have a closed-loop shape including sides of a straight line and/or a curved line. For example, the display area DA may have shapes, such as a polygonal shape, a circular shape, a semicircular, and an elliptical shape.

In embodiments, the display panel DP may have a flat display surface. In other embodiments, the display panel DP may have a display surface that is at least partially round. In embodiments, the display panel DP may be bendable, foldable, or rollable. In these cases, the display panel DP and/or the substrate of the display panel DP may include materials with flexible properties.

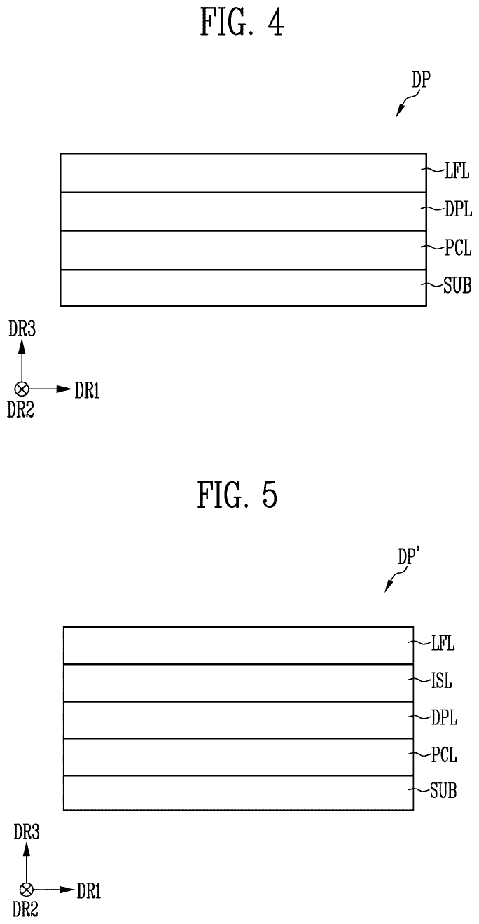

FIG. 4 is a cross-sectional view of a display panel in accordance with one or more embodiments.

Referring to FIG. 4, the display panel DP may include a substrate SUB, and a pixel circuit layer PCL, a display element layer DPL, and a light functional layer LFL, which are sequentially stacked on the substrate SUB in a third direction DR3 crossing the first and second directions DR1 and DR2.

The substrate SUB may be made of an insulating material, such as glass or a resin. For example, the substrate SUB may include a glass substrate. As another example, the substrate SUB may include a polyimide (PI) substrate. As yet another example, the substrate SUB may include a silicon wafer substrate formed using a semiconductor process.

In embodiments, the substrate SUB may be made of a flexible material to be bendable or foldable, and may have a single-layered structure or a multi-layered structure. For example, the flexible material may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited thereto.

The pixel circuit layer PCL is located on the substrate SUB. The pixel circuit layer PCL may include insulating layers and semiconductor patterns and conductive patterns located between the insulating layers. The conductive patterns of the pixel circuit layer PCL may function as circuit elements, wires, and the like.

The circuit elements of the pixel circuit layer PCL may include the sub-pixel circuit SPC (see FIG. 2) of each of the sub-pixels SP of FIG. 3. In other words, the circuit elements of the pixel circuit layer PCL may be provided as transistors and one or more capacitors of the sub-pixel circuit SPC.

The wires of the pixel circuit layer PCL may include wires connected to the sub-pixels SP. The wires of the pixel circuit layer PCL may include various signal lines and/or voltage lines required to drive the display element layer DPL.

The display element layer DPL is located on the pixel circuit layer PCL. The display element layer DPL may include light-emitting elements of the sub-pixels SP.

The light functional layer LFL may be located on the display element layer DPL. The light functional layer LFL may include light conversion patterns having color conversion particles and/or scattering particles. For example, the color conversion particles may include quantum dots. The quantum dots may change the wavelength (or color) of light emitted from the display element layer DPL. The light functional layer LFL may further include light scattering patterns with scattering particles. In embodiments, the light conversion patterns and the light scattering patterns may be omitted.

The light functional layer LFL may further include a color filter layer including color filters. The color filter may selectively transmit light of a corresponding wavelength (or a corresponding color). In embodiments, the color filter layer may be omitted.

A window for protecting an exposed surface (or upper surface) of the display panel DP may be provided on the light functional layer LFL. The window may protect the display panel DP from external impact. The window may be coupled to the light functional layer LFL through an optically transparent adhesive (bonding) member. The window may have a multi-layered structure selected from a glass substrate, a plastic film, and a plastic substrate. The multi-layered structure may be formed through a continuous process or an adhesive process using an adhesive layer. All or a portion of the window may be flexible.

FIG. 5 is a cross-sectional view of a display panel in accordance with one or more embodiments.

Referring to FIG. 5, a display panel DP′ may include a substrate SUB, a pixel circuit layer PCL, a display element layer DPL, an input sensing layer ISL, and a light functional layer LFL. The substrate SUB, the pixel circuit layer PCL, the display element layer DPL, and the light functional layer LFL are configured in the same manner as the substrate SUB, the pixel circuit layer PCL, the display element layer DPL, and the optical function layer LFL described with reference to FIG. 4. Hereinafter, redundant descriptions thereof will be omitted.

The input sensing layer ISL may detect a user input on an upper surface (or display surface) of the display panel DP′. The input sensing layer ISL may include components suitable for sensing an external object, such as a user's hand or pen. For example, the input sensing layer ISL may include touch electrodes.

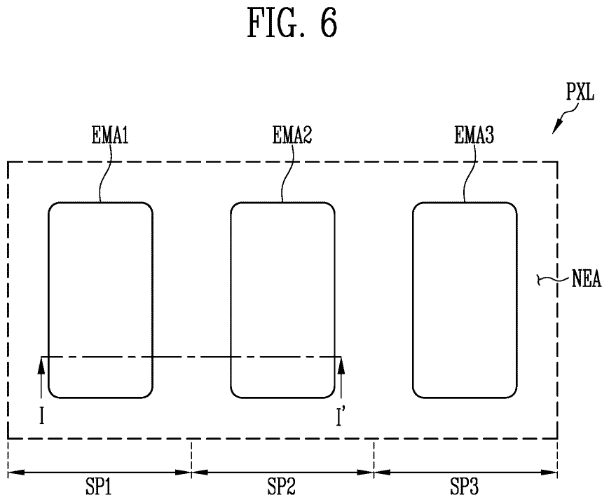

FIG. 6 is a plan view of a pixel in accordance with one or more embodiments.

Referring to FIG. 6, a pixel PXL may include the first to third sub-pixels SP1, SP2, and SP3 located in the first direction DR1.

The first sub-pixel SP1 may include a first light-emitting area EMA1, and a non-light-emitting area NEA around the first light-emitting area EMA1. The second sub-pixel SP2 may include a second light-emitting area EMA2, and a non-light-emitting area NEA around the second light-emitting area EMA2. The third sub-pixel SP3 may include a third light-emitting area EMA3, and a non-light-emitting area NEA around the third light-emitting area EMA3.

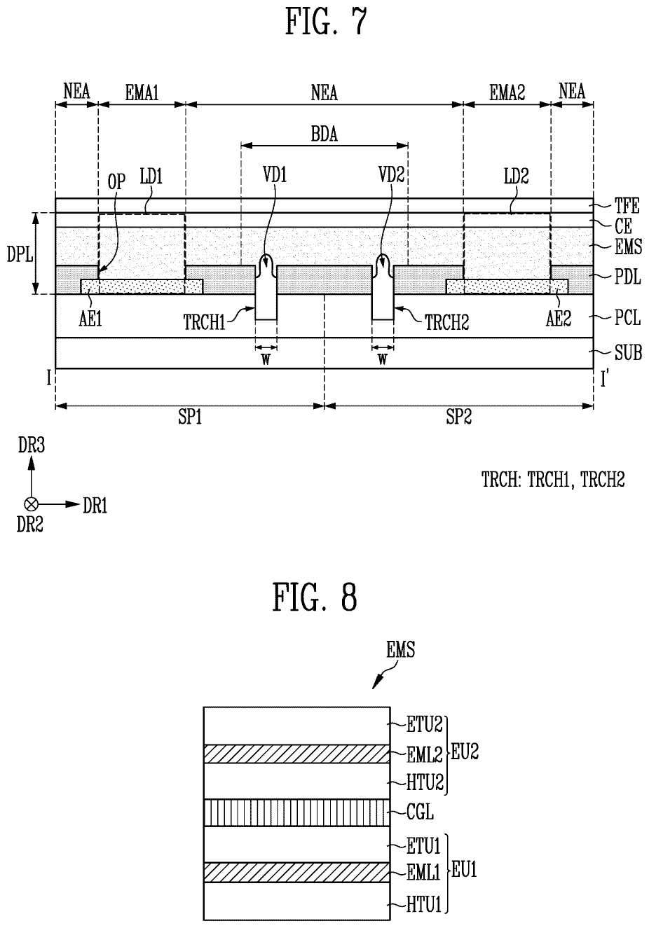

The first light-emitting area EMA1 may be an area in which light is emitted from a portion of the light-emitting structure EMS (see FIG. 7) corresponding to the first sub-pixel SP1. The second light-emitting area EMA2 may be an area in which light is emitted from a portion of the light-emitting structure EMS corresponding to the second sub-pixel SP2. The third light-emitting area EMA3 may be an area in which light is emitted from a portion of the light-emitting structure EMS corresponding to the third sub-pixel SP3.

FIG. 7 a cross-sectional view taken along the line I-I′ of FIG. 6 in accordance with one or more embodiments.

Referring to FIG. 7, a pixel circuit layer PCL may be located on the substrate SUB. The pixel circuit layer PCL may include insulating layers, semiconductor patterns, and conductive patterns stacked on the substrate SUB. The insulating layers may include a buffer layer, one or more interlayer insulating layers, and one or more passivation layers. The semiconductor patterns and the conductive patterns may be located between the insulating layers. The conductive patterns may function as at least some of circuit elements, wires, and the like

The conductive patterns may include at least one of copper (Cu), molybdenum (Mo), tungsten (W), aluminum neodymium (AlNd), titanium (Ti), aluminum (AI), and silver (Ag), but embodiments are not limited thereto.

The circuit elements may include the sub-pixel circuit SPC (see FIG. 2) for each of first and second sub-pixels SP1 and SP2. The sub-pixel circuit SPC may include transistors and one or more capacitors. Each transistor may include a semiconductor portion including a source region, a drain region, and a channel region, and a gate electrode overlapping the semiconductor portion. In embodiments, when the substrate SUB is provided as a silicon substrate, the semiconductor portion may be included in the substrate SUB, and the gate electrode may be included in the pixel circuit layer PCL as the conductive pattern of the pixel circuit layer PCL. In embodiments, when the substrate SUB is provided as a glass substrate or a PI substrate, the semiconductor portion and the gate electrode may be included in the pixel circuit layer PCL. Each capacitor may include electrodes spaced apart from each other. For example, each capacitor may include electrodes spaced apart from each other on a plane defined by the first and second directions DR1 and DR2. For example, each capacitor may include electrodes spaced apart from each other in the third direction DR3 with an insulating layer therebetween.

The wires of the pixel circuit layer PCL may include signal lines connected to each of the first and second sub-pixels SP1 and SP2 for example, a gate line, a light-emitting control line, and a data line. The wires may further include the wire connected to the first power voltage node VDDN of FIG. 2. In addition, the wires may further include the wire connected to the second power voltage node VSSN of FIG. 2.

In embodiments, a via layer may be located on the pixel circuit layer PCL. The via layer covers the pixel circuit layer PCL, and may have an overall flat surface. The via layer may include at least one of a silicon oxide (SiOx), a silicon nitride (SiNx), and a silicon carbon nitride (SiCN), but embodiments are not limited thereto.

The display element layer DPL may be located on the pixel circuit layer PCL. The display element layer DPL may include first and second anodes AE1 and AE2, a pixel-defining layer PDL, a light-emitting structure EMS, and a cathode CE.

The first and second anodes AE1 and AE2 may be located on the pixel circuit layer PCL. The first and second anodes AE1 and AE2 may be spaced apart from each other. For example, the first and second anodes AE and AE2 may be located in the first and second sub-pixels SP1 and SP2, respectively. The first anode AE1 may be provided as the anode AE (see FIG. 2) included in the first sub-pixel SP1. The second anode AE2 may be provided as the anode AE included the second sub-pixel SP2.

The first and second anodes AE1 and AE2 may include at least one of a transparent conductive materials, such as an indium tin oxide (ITO), an indium zinc oxide (IZO), a zinc oxide (ZnOx), an indium gallium zinc oxide (IGZO), and/or an indium tin zinc oxide (ITZO). However, the materials of the first and second anodes AE1 and AE2 are not limited thereto. For example, the first and second anodes AE1 and AE2 may include titanium nitride (TiN).

The pixel-defining layer PDL may be located on portions of the first and second anodes AE1 and AE2 and the pixel circuit layer PCL. The pixel-defining layer PDL may include an opening OP exposing a portion of each of the first and second anodes AE1 and AE2. The opening OP of the pixel-defining layer PDL may define the light-emitting area for each of the first and second sub-pixels SP1 and SP2. In other words, the pixel-defining layer PDL may define the first and second light-emitting areas EMA1 and EMA2 while being located in the non-light-emitting area NEA.

The pixel-defining layer PDL may include a plurality of inorganic insulating layers. Each of the plurality of inorganic insulating layers may include at least one of a silicon oxide (SiOx) and a silicon nitride (SiNx). For example, the pixel-defining layer PDL may include first to third inorganic insulating layers sequentially stacked, and each of the first to third inorganic insulating layers may include a silicon nitride, a silicon oxide, and a silicon oxynitride. However, embodiments are not limited thereto.

At least one trench TRCH may be provided in the boundary area BDA between the sub-pixels that are adjacent to each other. For example, the first and second trenches TRCH1 and TRCH2 may be provided in the boundary area BDA between the first and second sub-pixels SP1 and SP2.

At least one trench TRCH may cause a discontinuity to be formed within the light-emitting structure EMS in the boundary area BDA. For example, the light-emitting structure EMS may be disconnected or bent in the boundary area BDA by the first and second trenches TRCH1 and TRCH2.

At least one trench TRCH may be provided in or on the pixel-defining layer PDL. For example, the pixel-defining layer PDL may include the first and second trenches TRCH1 and TRCH2 in the boundary area BDA. The first and second trenches TRCH1 and TRCH2 may penetrate the pixel-defining layer PDL, and may partially penetrate the pixel circuit layer PCL, but embodiments are not limited thereto. For example, the first and second trenches TRCH1 and TRCH2 may penetrate the pixel-defining layer PDL, and may not penetrate the pixel circuit layer PCL.

In FIG. 7, it is shown that two trenches TRCH, that is, the first and second trenches TRCH1 and TRCH2, are provided in the boundary area BDA, but embodiments are not limited thereto. For example, the pixel-defining layer PDL may include one trench TRCH in the boundary area BDA. For example, the pixel-defining layer PDL may include three or more trenches TRCH in the boundary area BDA.

Due to the first and second trenches TRCH1 and TRCH2, discontinuous portions, such as the first void VD1 and the second void VD2 may be formed in the light-emitting structure EMS in the boundary area BDA. Some of the plurality of layers stacked in the light-emitting structure EMS may be disconnected or bent by the first and second voids VD1 and VD2. For example, at least one charge generation layer and/or hole injection layer included in the light-emitting structure EMS may be disconnected by the first and second voids VD1 and VD2. As described above, due to the first and second trenches TRCH1 and TRCH2, the portions of the light-emitting structure EMS included in the first and second sub-pixels SP1 and SP2 may be at least partially separated.

The width of at least one trench TRCH may be about 70 nm or less. The width of the trench TRCH may be a length measured in the first direction DR1. For example, the width w of each of the first and second trenches TRCH1 and TRCH2 may be about 70 nm or less. When the first and second trenches TRCH1 and TRCH2 are formed in a fine pattern under the above-described conditions, a discontinuous portion may be formed in the light-emitting structure EMS without the cathode CE being disconnected.

In FIG. 7, it is illustrated that the first and second voids VD1 and VD2 are formed in the light-emitting structure EMS in the boundary area BDA, but embodiments are not limited thereto. For example, a valley of a concave shape may be formed in the light-emitting structure EMS in the boundary area BDA. Depending on the shapes of the first and second trenches TRCH1 and TRCH2, the discontinuities formed in the light-emitting structure EMS may vary.

The light-emitting structure EMS may be located on the first and second anodes AE1 and AE2 exposed by the opening OP of the pixel-defining layer PDL. The light-emitting structure EMS may fill the opening OP of the pixel-defining layer PDL, and may be located entirely across the first and second sub-pixels SP1 and SP2. As described above, the light-emitting structure EMS may be at least partially disconnected or bent in the boundary area BDA by at least one trench TRCH. Accordingly, when the display panel DP (see FIG. 3) is operated, the current flowing from each of the first and second sub-pixels SP1 and SP2 to the sub-pixels adjacent thereto through layers included in the light-emitting structure EMS may be reduced (or removed). In other words, lateral leakage may be reduced (or removed), thereby improving the efficiency, reliability, and lifespan characteristics of the display panel DP.

The cathode CE may be located on the light-emitting structure EMS. The cathode CE may be commonly provided in the first and second sub-pixels SP1 and SP2. The cathode CE may function as a half mirror that partially transmits and partially reflects light emitted from the light-emitting structure EMS.

The first anode AE1, the portion of the light-emitting structure EMS overlapping the first anode AE1, and the portion of the cathode CE overlapping the first anode AE1 may configure the first light-emitting element LD1. The second anode AE2, the portion of the light-emitting structure EMS overlapping the second anode AE2, and the portion of the cathode CE overlapping the second anode AE2 may configure the second light-emitting element LD2.

The encapsulation layer TFE may be located on the cathode CE. The encapsulation layer TFE may reduce or prevent oxygen and/or moisture from penetrating into the display element layer DPL.

So far, the adjacent sub-pixels, that is, the first and second sub-pixels SP1 and SP2 among the first to third sub-pixels SP1, SP2, and SP3 of FIG. 6 have been described. The third sub-pixel SP3 of FIG. 6 may also be configured in the same manner as the first and second sub-pixels SP1 and SP2 within a range not described otherwise herein.

FIG. 8 is a cross-sectional view of a light-emitting structure in accordance with one or more embodiments.

Referring to FIG. 8, the light-emitting structure EMS may have a tandem structure in which first and second light-emitting portions EU1 and EU2 are stacked.

Each of the first and second light-emitting portions EU1 and EU2 may include at least one light-emitting layer that generates light according to a current applied thereto. The first light-emitting portion EU1 may include a first light-emitting layer EML1, a first electron transport portion ETU1, and a first hole transport portion HTU1. The first light-emitting layer EML1 may be located between the first electron transport portion ETU1 and the first hole transport portion HTU1. The second light-emitting portion EU2 may include a second light-emitting layer EML2, a second electron transport portion ETU2, and a second hole transport portion HTU2. The second light-emitting layer EML2 may be located between the second electron transport portion ETU2 and the second hole transport portion HTU2.

Each of the first and second hole transport portions HTU1 and HTU2 may include at least one of a hole injection layer and a hole transport layer, and may further include a hole buffer layer, an electron-blocking layer, or the like as needed. The first and second hole transport portions HTU1 and HTU2 may have the same configuration or different configurations.

Each of the first and second electron transport portions ETU1 and ETU2 may include at least one of an electron injection layer and an electron transport layer, and may further include an electron buffer layer and a hole-blocking layer as needed. The first and second electron transport portions ETU1 and ETU2 may have the same configuration or different configurations.

A connection layer, which may be provided in the form of a charge generation layer CGL, may be located between the first light-emitting portion EU1 and the second light-emitting portion EU2 to connect them to each other. In embodiments, the charge generation layer CGL may have a stacked structure of a p dopant layer and an n dopant layer. For example, the p dopant layer may include a p-type dopant, such as HAT-CN, TCNQ, and NDP-9, and the n dopant layer may include an alkali metal, an alkaline earth metal, a lanthanide-based metal, or a combination thereof. However, embodiments are not limited thereto.

In embodiments, the first light-emitting layer EML1 and the second light-emitting layer EML2 may generate light of different colors. The light emitted from each of the first light-emitting layer EML1 and the second light-emitting layer EML2 may be mixed to be recognized as white light. For example, the first light-emitting layer EML1 may generate blue-colored light, and the second light-emitting layer EML2 may generate yellow-colored light. In embodiments, the second light-emitting layer EML2 may include a structure in which a first sub-light-emitting layer configured to generate red-colored light and a second sub-light-emitting layer configured to generate green-colored light are stacked. The red-colored light and the green-colored light may be mixed to provide yellow-colored light. In this case, an intermediate layer configured to perform a function of transporting holes and/or reducing or preventing transport of electrons may be further located between the first and second sub-light-emitting layers.

In other embodiments, the first light-emitting layer EML1 and the second light-emitting layer EML2 may generate light of the same color.

The light-emitting structure EMS may be formed through a vacuum deposition method, an inkjet printing method, or the like, but embodiments are not limited thereto.

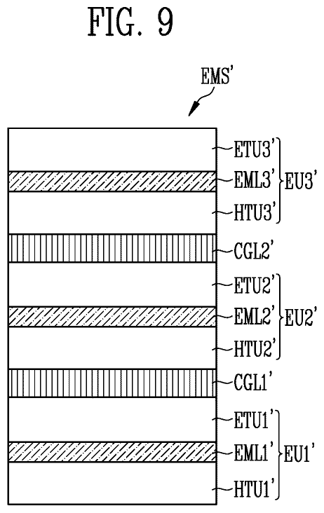

FIG. 9 is a cross-sectional view of a light-emitting structure in accordance with one or more embodiments.

Referring to FIG. 9, a light-emitting structure EMS' may have a tandem structure in which first to third light-emitting portions EU1′ to EU3′ are stacked.

Each of the first to third light-emitting portions EU1′ to EU3′ may include a light-emitting layer that generates light according to a current applied thereto. The first light-emitting portion EU1′ may include a first light-emitting layer EML1′, a first electron transport portion ETU1′, and a first hole transport portion HTU1′. The first light-emitting layer EML1′ may be located between the first electron transport portion ETU1′ and the first hole transport portion HTU1′. The second light-emitting portion EU2′ may include a second light-emitting layer EML2′, a second electron transport portion ETU2′, and a second hole transport portion HTU2′. The second light-emitting layer EML2′ may be located between the second electron transport portion ETU2′ and the second hole transport portion HTU2′. The third light-emitting portion EU3′ may include a third light-emitting layer EML3′, a third electron transport portion ETU3′, and a third hole transport portion HTU3′. The third light-emitting layer EML3′ may be located between the third electron transport portion ETU3′ and the third hole transport portion HTU3′.

Each of the first to third hole transport portions HTU1′ to HTU3′ may include at least one of a hole injection layer and a hole transport layer, and may further include a hole buffer layer, an electron-blocking layer, or the like as needed. The first to third hole transport portions HTU1′ to HTU3′ may have the same configuration or different configurations.

Each of the first to third electron transport portions ETU1′ to ETU3′ may include at least one of an electron injection layer and an electron transport layer, and may further include an electron buffer layer and a hole-blocking layer as needed. The first to third electron transport portions ETU1′ to ETU3′ may have the same configuration or different configurations.

A first charge generation layer CGL1′ is located between the first light-emitting portion EU1′ and the second light-emitting portion EU2′. A second charge generation layer CGL2′ is located between the second light-emitting portion EU2′ and the third light-emitting portion EU3′.

In embodiments, the first to third light-emitting layers EML1′ to EML3′ may generate light of different colors. Light emitted from each of the first to third light-emitting layers EML1′ to EML3′ may be mixed to be viewed as white light. For example, the first light-emitting layer EML1′ may generate light of a blue color, the second light-emitting layer EML2′ may generate light of a green color, and the third light-emitting layer EML3′ may generate light of a red color.

In other embodiments, two or more of the first to third light-emitting layers EML1′ to EML3′ may generate light of the same color.

Unlike illustrated in FIG. 8 and FIG. 9, each light-emitting structure EMS of FIG. 7 may include one light-emitting portion. The light-emitting portions respectively included in the first to third sub-pixels SP1, SP2, and SP3 (see FIG. 6) may be configured to emit light of different colors. For example, the light-emitting portion included in the first sub-pixel SP1 may emit red-colored light, the light-emitting portion included in the second sub-pixel SP2 may emit green-colored light, and the light-emitting portion included in the third sub-pixel SP3 may emit blue-colored light. In this case, unlike shown in FIG. 7, the light-emitting portions of the first and second sub-pixels SP1 and SP2 are separated from each other, and each of them may be located in the opening OP of the pixel-defining layer PDL.

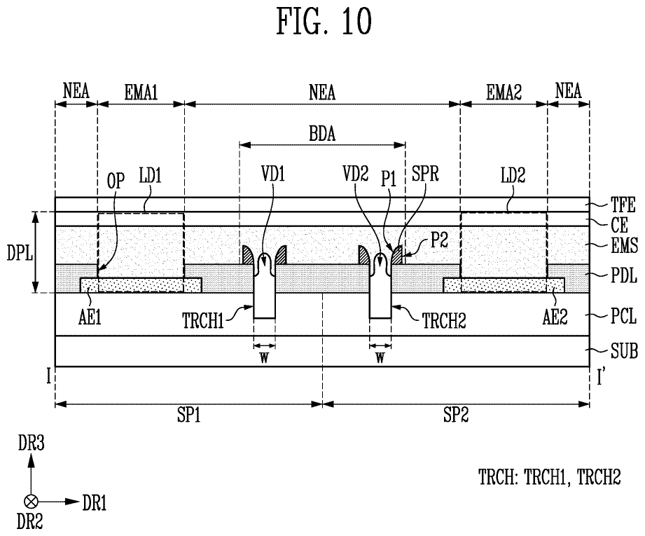

FIG. 10 is a cross-sectional view taken along the line I-I′ of FIG. 6 in accordance with one or more embodiments. In describing FIG. 10, descriptions of contents overlapping those of FIG. 7 will be simplified or omitted.

Referring to FIG. 10, the display element layer DPL may further include a spacer SPR. The spacer SPR may be located on a portion of the pixel-defining layer PDL adjacent to at least one trench TRCH. For example, the spacer SPR may be located on portions of the pixel-defining layer PDL respectively adjacent to the first and second trenches TRCH1 and TRCH2. The spacer SPR may not be only used when forming the above-described fine patterned trench TRCH, but may also be used to maintain a gap with the deposition mask when forming the light-emitting structure EMS. In other words, the spacer SPR may be formed as an integrated structure with the trench TRCH, thereby securing the margin of the design rule. The spacer SPR may include silica, silicon nitride, and the like, but embodiments are not limited thereto.

The width of the spacer SPR may be the same as the width of the trench TRCH. The width of the spacer SPR may be a length measured in the first direction DR1. For example, the width of the spacer SPR may be the same as the width w of each of the first and second trenches TRCH1 and TRCH2. The width of the spacer SPR may refer to a gap (or a minimum gap) between the first portions P1, which will be described later.

The spacer SPR may have a symmetrical structure with respect to the trench TRCH. For example, in a plan view, the spacer SPR may have a symmetrical structure with respect to each of the first and second trenches TRCH1 and TRCH2. In the embodiments, shapes of the first portions P1 facing the trench TRCH of the spacer SPR and the second portions P2 not facing the trench TRCH thereof may be different from each other. For example, the first portions P1 respectively facing the first and second trenches TRCH1 and TRCH2 of the spacer SPR may be round, and the second portions P2 not respectively facing the first and second trenches TRCH1 and TRCH2 of the spacer SPR may be flat. In this case, the width of the spacer SPR described above may mean the minimum gap between the first portions P1.

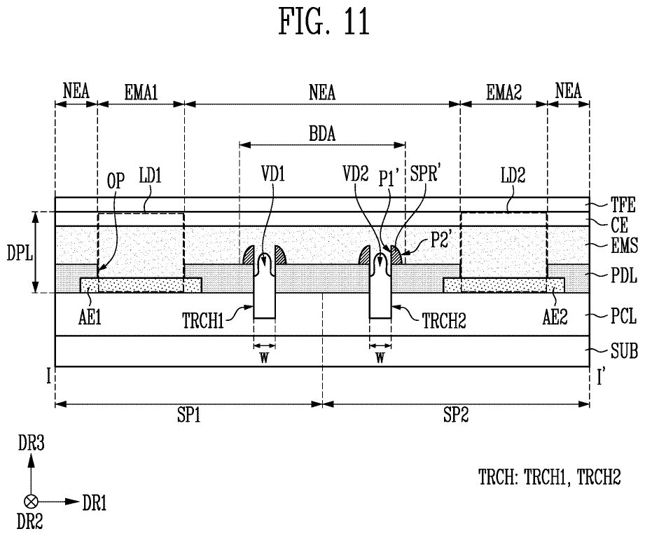

FIG. 11 is a cross-sectional view taken along the line I-I′ of FIG. 6 in accordance with one or more embodiments. In describing FIG. 11, descriptions of contents overlapping those of FIG. 7 and FIG. 10 will be simplified or omitted.

Referring to FIG. 11, the display element layer DPL may further include a spacer SPR′. The spacer SPR′ may have a different shape from the spacer SPR of FIG. 10. For example, the first portions P1′ respectively facing the first and second trenches TRCH1 and TRCH2 of the spacer SPR′ may be flat, and the second portions P2′ not respectively facing the first and second trenches TRCH1 and TRCH2 of the spacer SPR′ may be round. In this case, the width of the spacer SPR′ may be equal to the width w of each of the first and second trenches TRCH1 and TRCH2, and the width of the spacer SPR′ may mean a gap between the first portions P1′.

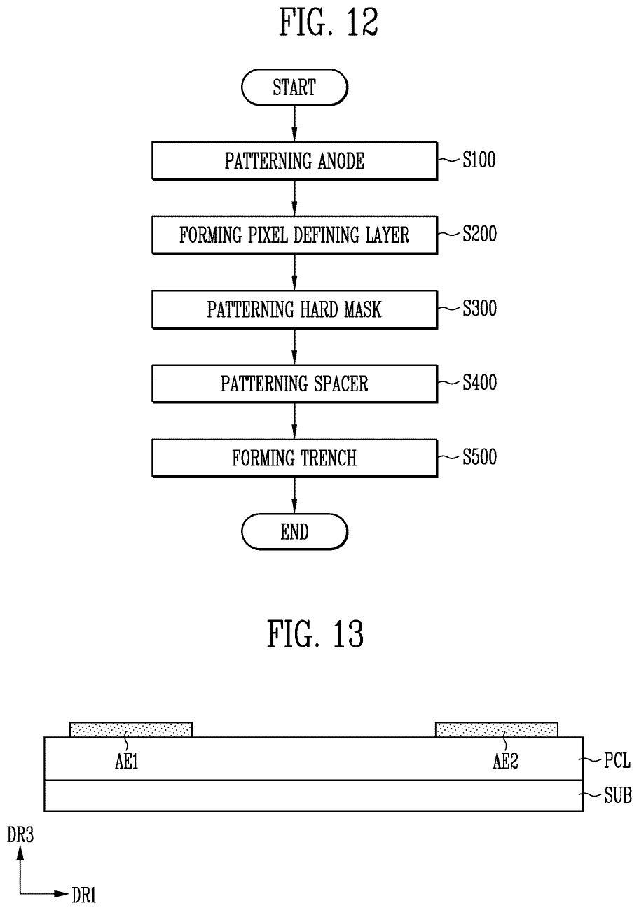

FIG. 12 is a flowchart describing a method of manufacturing a display device in accordance with one or more embodiments. FIGS. 13 to 18 are cross-sectional views illustrating steps of a method of manufacturing the display device in accordance with one or more embodiments.

Referring to FIG. 12 and FIG. 13, patterning the anode (S100) may be performed. For example, the first and second anodes AE1 and AE2 spaced apart from each other may be formed on the pixel circuit layer PCL on the substrate SUB. The first anode AE1 may be patterned at a position corresponding to the first light-emitting area EMA1 (see FIG. 7), and the second anode AE2 may be patterned at a position corresponding to the second light-emitting area EMA2 (see FIG. 7).

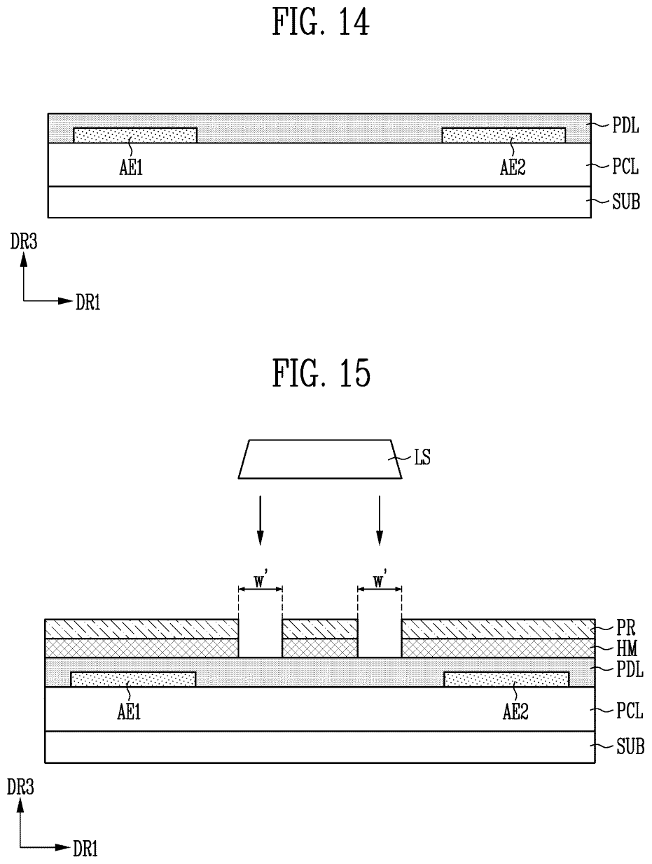

Referring to FIG. 12 and FIG. 14, then, forming the pixel-defining layer (S200) may be performed. For example, the pixel-defining layer PDL may be entirely formed on the pixel circuit layer PCL and the first and second anodes AE1 and AE2.

Referring to FIG. 12 and FIG. 15, then, patterning a hard mask (S300) may be performed. For example, a hard mask HM may be entirely formed on the pixel-defining layer PDL, and a photoresist PR may be entirely formed on the hard mask HM. Next, portions of the photoresist PR exposed to light may be removed through an exposure process and a development process using a light source LS. Then, portions of the hard mask HM exposed (or that do not overlap the photoresist PR) may be removed through an etching process. In FIG. 15, the photoresist PR remaining on the hard mask HM is illustrated, but this is for better understanding and ease of description, and the photoresist PR remaining after patterning the hard mask HM may be removed.

In the above-described exposure process, various exposers may be used as the light source LS depending on the wavelength of light. For example, the light source LS may be a KrF exposer (e.g., about 248 nm), an ArF exposer (e.g., about 193 nm), or an ArFi exposer (e.g., about 193 nm). The numbers in the parentheses may refer to the wavelength of light. The shorter the wavelength of the light source LS used in the exposure process, the more likely it is to form a fine pattern. However, it may be difficult to form the first and second trenches TRCH1 and TRCH2 (see FIG. 7) of fine patterns with a width w (see FIG. 7) of about 70 nm or less through the above-mentioned exposers. As shown in FIG. 15, the width w′ of the fine pattern (or the hard mask HM) may be greater than the width w of the first and second trenches TRCH1 and TRCH2.

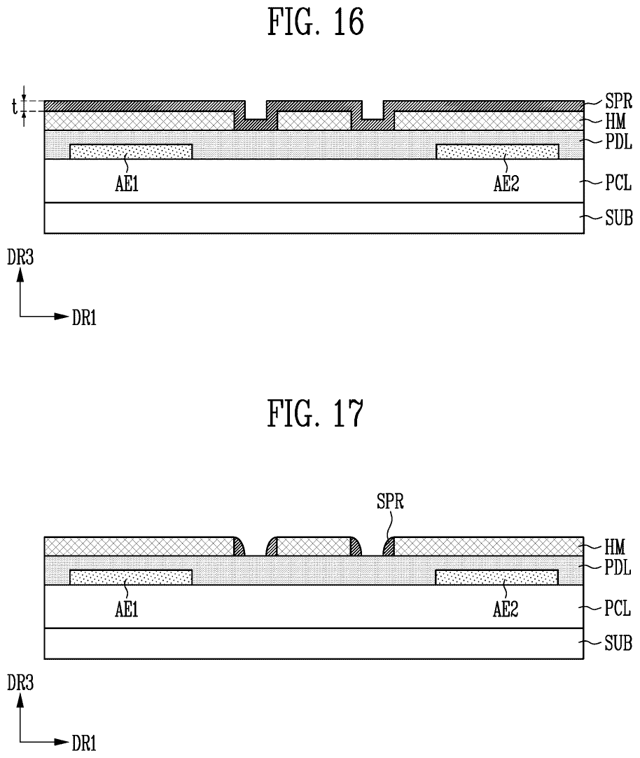

Referring to FIG. 12, FIG. 16, and FIG. 17, next, patterning the spacer (S400) for solving the above-described problem may be performed. For example, the spacer SPR (e.g., a spacer material) may be entirely formed on the pixel-defining layer PDL and the hard mask HM. The spacer SPR may be deposited by methods, such as chemical vapor deposition, atomic layer deposition, conformal coating, and the like, but embodiments are not limited thereto. Portions of the spacer SPR on exposed portions of the pixel-defining layer PDL (or not overlapping the hard mask HM) may have steps, but embodiments are not limited thereto. In embodiments, the thickness t of the spacer SPR is not particularly limited, but considering maintaining the gap with the above-described deposition mask, the thickness t of the spacer SPR may be at least about 2000 Å (angstrom). The thickness t of the spacer SPR may be a length measured in the third direction DR3.

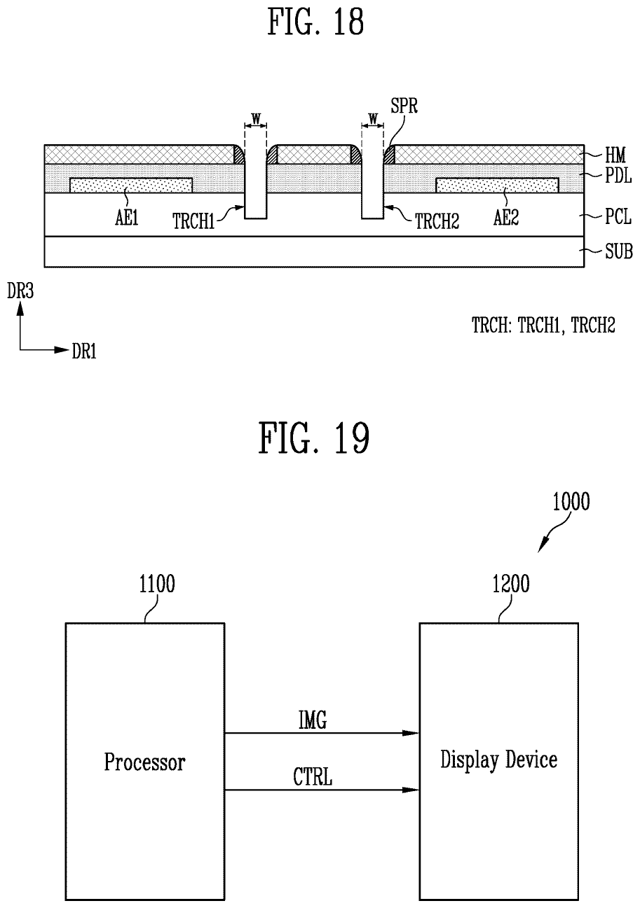

Next, the spacer SPR may be patterned. For example, portions overlapping the hard mask HM and portions overlapping the first and second trenches TRCH1 and TRCH2 (see FIG. 18) of the spacer SPR may be removed. In this case, the spacer SPR adjacent to the lateral surfaces of the hard mask HM may be formed by adjusting the etch rate so that the vertical etch rate is greater than the lateral etch rate. The spacer SPR may be patterned through a process, such as etch back or chemical mechanical planarization (CMP), but embodiments are not limited thereto. Through the patterning of the spacer (S400), not only the spacer SPR shown in FIG. 10 and FIG. 17, but also the spacer SPR′ shown in FIG. 11, may be formed.

Referring to FIG. 12 and FIG. 18, then, forming the trench (S500) may be performed. At least one trench TRCH may be formed through an etching process. For example, the first and second trenches TRCH1 and TRCH2 may be formed by removing exposed portions (or portions not overlapping the hard mask HM and spacer SPR) of the pixel-defining layer PDL and of the pixel circuit layer PCL therebelow by using the spacer SPR and the hard mask HM as a mask. In this case, the width w of each of the first and second trenches TRCH1 and TRCH2 may be about 70 nm or less. Due to the spacer SPR, the first and second trenches TRCH1 and TRCH2 may be formed to have a fine width (w) that exceeds the physical limit (that is, width w′) of the light source LS shown in FIG. 15.

The hard mask HM and the spacer SPR may be removed after the forming of the trench (S500). Next, the opening OP (see FIG. 10) exposing each of the first and second anodes AE1 and AE2 may be formed by etching the pixel-defining layer PDL. Next, the light-emitting structure EMS, the cathode CE, the encapsulation layer TFE, and the like may be sequentially deposited (see FIG. 10).

After the forming of the trench (S500), the hard mask HM may be removed, while the spacer SPR may remain. Next, the opening OP (see FIG. 11) exposing each of the first and second anodes AE1 and AE2 may be formed by etching the pixel-defining layer PDL. Next, the light-emitting structure EMS may be deposited while maintaining the gap with the deposition mask using the spacer SPR (see FIG. 11). Next, the cathode CE, the encapsulation layer TFE, and the like may be sequentially deposited (see FIG. 11).

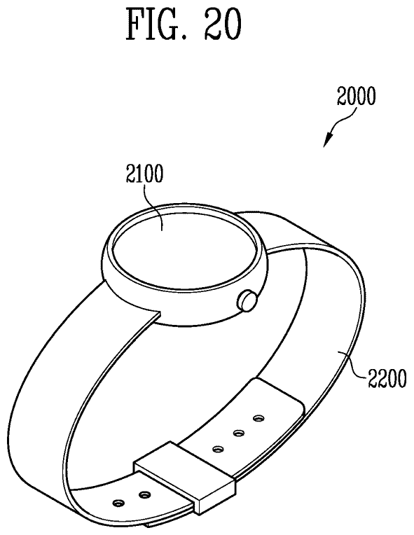

FIG. 19 is a block diagram of a display system in accordance with one or more embodiments.

Referring to FIG. 19, a display system 1000 may include a processor 1100 and a display device 1200.

The processor 1100 may perform various tasks and calculations. In embodiments, the processor 1100 may include an application processor, a graphics processor, a microprocessor, a central processing unit (CPU), and the like. The processor 1100 may be connected to and step other constituent elements of the display system 1000 through a bus system.

The processor 1100 may transmit image data IMG and a control signal CTRL to the display device 1200. The display device 1200 may display an image based on the image data IMG and the control signal CTRL. The display device 1200 may be configured similarly to the display device DD described with reference to FIG. 1. In this case, the image data IMG and the control signal CTRL may be provided as the input image data IMG and the control signal CTRL of FIG. 1, respectively.

The display system 1000 may include a computing system that provides image display functions, such as a smart watch, a mobile phone, a smart phone, a portable computer, a tablet personal computer (PC), a watch phone, an automatic display, a smart glass, a portable multimedia player (PMP), a navigation system, and an ultra-mobile personal computer (UMPC). In addition, the display system 1000 may include at least one of a head-mounted display device (HMD), a virtual reality (VR) device, a mixed reality (MR) device, and an augmented reality (AR) device.

FIGS. 20 to 23 are perspective views of application examples of the display system of FIG. 19 in accordance with one or more embodiments.

Referring to FIG. 20, the display system 1000 of FIG. 19 may be applied to a smart watch 2000 including a display portion 2100 and a strap portion 2200.

The smart watch 2000 may be a wearable electronic device. For example, the smart watch 2000 may have a structure in which the strap portion 2200 is mounted on the user's wrist. Here, the display system 1000 and/or the display device 1200 may be applied to the display portion 2100, so that image data including time information may be provided to the user.

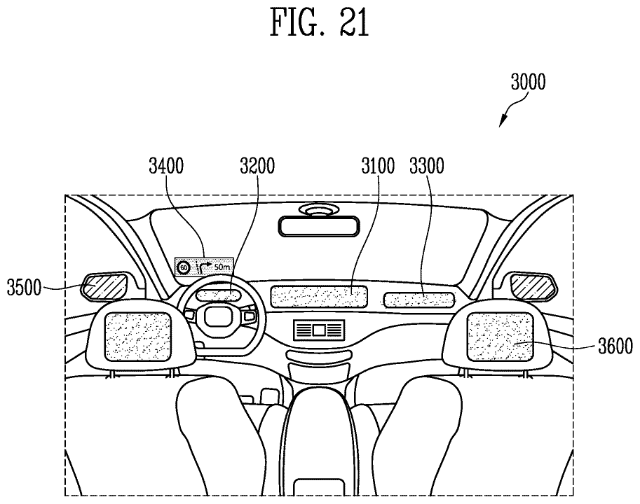

Referring to FIG. 21, the display system 1000 of FIG. 19 may be applied to an automotive display system 3000. Here, the automotive display system 3000 may include a computing system that is provided inside and/or outside the vehicle to provide image data.

For example, the display system 1000 and/or the display device 1200 may be applied to at least one of an infotainment panel 3100, a cluster 3200, a co-driver display 3300, a head-up display 3400, a side mirror display 3500, and a rear-seat display 3600, which are provided in the vehicle.

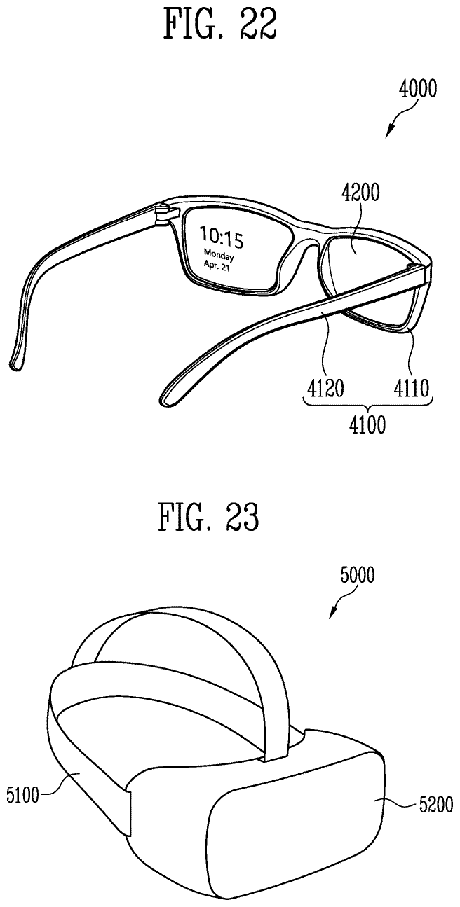

Referring to FIG. 22, the display system 1000 of FIG. 19 may be applied to smart glasses 4000. The smart glasses 4000 may be a wearable electronic device that may be worn on the user's head. For example, the smart glasses 4000 may be a wearable device for augmented reality.

The smart glasses 4000 may include a frame 4100 and a lens portion 4200. The frame 4100 may include a housing 4110 supporting the lens portion 4200 and a leg portion 4120 for the user to wear. The leg portion 4120 may be connected to the housing 4110 through a hinge to be folded or unfolded with respect to the housing 4110.

A battery, a touch pad, a microphone, and a camera may be embedded in the frame 4100. In addition, a projector that outputs light and a processor that controls an optical signal and the like may be embedded in the frame 4100.

The lens portion 4200 may include an optical member that transmits light or reflects light. For example, the lens portion 4200 may include glass, a transparent synthetic resin, or the like.

For the user's eyes to recognize visual information, the lens portion 4200 may reflect an image by an optical signal transmitted from the projector of the frame 4100 by a rear surface of the lens portion 4200 (for example, a surface facing the user's eye). For example, the user may recognize visual information, such as time and date displayed on the lens portion 4200. In this case, the projector and/or the lens portion 4200 may be a type of display device. The display device 1200 may be applied to the projector and/or the lens portion 4200.

Referring to FIG. 23, the display system 1000 of FIG. 19 may be applied to a head-mounted display device 5000.

The head-mounted display device 5000 may be a wearable electronic device that may be worn on the user's head. For example, the head-mounted display device 5000 may be a wearable device for virtual reality or mixed reality.

The head-mounted display device 5000 may include a head-mounted band 5100 and a display device accommodation case 5200. The head-mounted band 5100 may be connected to the display device accommodation case 5200. The head-mounted band 5100 may include a horizontal band and/or a vertical band for fixing the head-mounted display device 5000 to the user's head. The horizontal band may be configured to surround the side portion of the user's head, and the vertical band may be configured to surround the upper portion of the user's head. However, embodiments are not limited thereto. For example, the head-mounted band 5100 may be implemented in the form of a spectacle frame, a helmet, or the like.

The display device accommodation case 5200 may accommodate the display system 1000 and/or the display device 1200.

The embodiments described in detail above are provided to explain the present disclosure, but these embodiments are not intended to limit the scope of the present disclosure. It should be understood by those skilled in the art that various changes, substitutions, and alternations may be made therein without departing from the scope of the disclosure as defined by the following claims and their equivalents.

The scope of the present disclosure is not limited by detailed descriptions of the present specification and should be defined by the accompanying claims and their equivalents. Furthermore, all changes or modifications of the present disclosure derived from the claims, and equivalents thereof, should be construed as being included in the scope of the present disclosure. The embodiments may be combined to form additional embodiments.

What is claimed is:

1. A display device comprising:
a substrate;
a pixel circuit layer above the substrate;
anodes spaced apart from each other above the pixel circuit layer;
a pixel-defining layer partially on the pixel circuit layer and the anodes; and
at least one trench between the anodes, partially penetrating the pixel-defining layer and the pixel circuit layer, and having a width of about 70 nm or less.

2. The display device according to claim 1, further comprising a spacer above a portion of the pixel-defining layer adjacent to the trench.

3. The display device according to claim 2, wherein a width of the spacer is substantially equal to the width of the trench.

4. The display device according to claim 2, wherein the spacer has a symmetrical structure with respect to the trench.

5. The display device according to claim 4, wherein shapes of first portions of the spacer facing the trench, and shapes of second portions of the spacer not facing the trench, are different from each other.

6. The display device according to claim 5, wherein the first portions are round, and the second portions are flat.

7. The display device according to claim 5, wherein the first portions are flat, and the second portions are round.

8. A method of manufacturing a display device, the method comprising:
patterning anodes above a pixel circuit layer above a substrate;
forming a pixel-defining layer above the pixel circuit layer and the anodes;
patterning a hard mask above the pixel-defining layer;
patterning a spacer above the pixel-defining layer; and
forming at least one trench between the anodes, and partially penetrating the pixel-defining layer and the pixel circuit layer.

9. The method according to claim 8, wherein the patterning of the hard mask comprises:
forming the hard mask above the pixel-defining layer;
forming a photoresist above the hard mask;
exposing and developing the photoresist using a light source;
etching the hard mask; and
removing the photoresist.

10. The method according to claim 9, wherein the light source comprises a KrF exposer, ArF exposer, or ArFi exposer.

11. The method according to claim 8, wherein the patterning of the spacer comprises:
forming a spacer material above the hard mask and the pixel-defining layer; and
removing portions of the spacer material that overlap the hard mask and the trench.

12. The method according to claim 11, wherein a thickness of the spacer is at least about 2000 Å.

13. The method according to claim 8, wherein a width of the spacer is substantially equal to the width of the trench.

14. The method according to claim 8, wherein the spacer has a symmetrical structure with respect to the trench.

15. The method according to claim 14, wherein shapes of first portions of the spacer facing the trench, and shapes of second portions of the spacer not facing the trench, are different from each other.

16. The method according to claim 15, wherein the first portions are round, and the second portions are flat.

17. The method according to claim 15, wherein the first portions are flat, and the second portions are round.

18. The method according to claim 8, wherein a width of the trench is about 70 nm or less.

19. The method according to claim 8, further comprising removing the hard mask.

20. The method according to claim 19, further comprising removing the spacer.
